(19) United States
(12) Patent Application Publication
(10) Pub. No.: US 2011/0272008 A1
(43) Pub. Date: Nov. 10, 2011

(54) OXIDE NITRIDE STACK FOR BACKSIDE REFLECTOR OF SOLAR CELL

(75) Inventors: Hemant P. Mungekar, Campbell, CA (US); Mukul Agrawal, Fremont, CA (US); Michael P. Stewart, San Francisco, CA (US); Timothy W. Weidman, Sunnyvale, CA (US); Rohit Mishra, Santa Clara, CA (US); Sunhom Paak, Saratoga, CA (US)

(73) Assignee: APPLIED MATERIALS, INC., Santa Clara, CA (US)

(21) Appl. No.: 13/101,871

(22) Filed: May 5, 2011

Related U.S. Application Data
(60) Provisional application No. 61/332,554, filed on May 7, 2010.

(51) Int. Cl. H01L 31/02; H01L 31/18; B82Y 40/00; B82Y 99/00

(52) U.S. Cl. 136/252; 438/98; 977/755; 257/E31.124

(57) ABSTRACT

Embodiments of the invention generally provide methods for forming a multilayer rear surface passivation layer on a solar cell substrate. The method includes forming a silicon oxide sub-layer having a net charge density of less than or equal to 2.1×10¹¹ Coulombs/cm² on a rear surface of a p-type doped region formed in a substrate comprising semiconductor material, the rear surface opposite a light receiving surface of the substrate and forming a silicon nitride sub-layer on the silicon oxide sub-layer. Embodiments of the invention also include a solar cell device that may be manufactured according methods disclosed herein.

### CROSS-REFERENCE TO RELATED APPLICATIONS

This application claims benefit of U.S. Provisional Patent Application Ser. No. 61/332,554 (APPM/014741 L), filed May 7, 2010, which is herein incorporated by reference.

### BACKGROUND OF THE INVENTION

1. Field of the Invention

Embodiments of the present invention generally relate to the fabrication of solar cells and particularly to the rear surface passivation of silicon solar cells.

2. Description of the Related Art

Solar cells are photovoltaic devices that convert sunlight directly into electrical power. The most common solar cell material is silicon (Si), which is in the form of single, polycrystalline, multi-crystalline substrates, or amorphous films. Efforts to reduce the cost of manufacturing solar cells, and thus the cost of the resulting cell, while maintaining or increasing the overall efficiency of the solar cell produced are ongoing.

The efficiency of a solar cell may be enhanced by use of a passivation layer on the rear surface of a solar cell. When light passes from one medium to another, for example from air to glass, or from glass to silicon, some of the light may reflect off of the interface between the two media. The fraction of light reflected is a function of the difference in refractive index between the two media, wherein a greater difference in refractive indices of two adjacent media results in a higher fraction of light being reflected from the interface therebetween. Various layers disposed on the rear surface of the solar cell can reflect light back into the silicon to absorb the reflected light, such as caused by the interface between two media, and increase the efficiency of a solar cell.

The efficiency at which a solar cell converts incident light energy into electrical energy is adversely affected by a number of factors, including the fraction of incident light that is reflected off the light receiving surface of a solar cell and/or not reflected off the rear surface of a solar cell, and absorbed in the cell structure, such as a passivation layer, and the recombination rate of electrons and holes in a solar cell. Each time an electron-hole pair recombines, charge carriers are eliminated, thereby reducing the efficiency of the solar cell. Recombination may occur in the bulk silicon of a substrate, which is a function of the number of defects in the bulk silicon, or on the surface of a substrate, which is a function of how many dangling bonds, i.e., unterminated chemical bonds, are present. Moreover, the efficiency of the solar cell may be reduced due to a reduction in the carrier lifetime caused by a shunt current created at the rear surface of the solar cell. The shunt current may be formed by a buildup of excess negative charge near the rear surface of the solar cell due to the presence of an unwanted amount of positive charge in adjacent dielectric/passivation layers. The excess negative charge can leak into the nearby backside contacts causing recombination to occur at the contact interface, thereby reducing solar cell efficiency.

One function of a passivation layer is to minimize the carrier recombination at the rear surface a solar cell. One way to improve the passivation function of a passivation layer is to have a sufficient source of hydrogen (H) available in the passivation layer for bulk and surface passivation. Another way to improve the passivation layer function is to provide a negative charge or a limited amount of net positive charge in the passivation layer to prevent a shunt current from forming. Thorough passivation of a solar cell by using a passivation layer greatly improves the efficiency of the solar cell by reducing recombination rates. Patterning, however, of a rear surface passivation layer, such as when forming backside contacts, may also be difficult depending on the type of patterning processes used and type of passivation layer, resulting in slower throughput. Moreover, conventional passivation layer formation processes have been unable to provide a passivation layer having a desired amount of charge to prevent or at least reduce shunt current formation.

Therefore, there is a need for an improved method of forming a rear surface passivation layer that provides a net amount of charge to prevent shunt current formation, provides a source of H for bulk and/or surface passivation of the substrate, increases ease of patterning to form the back layer contact, and reflects light back into the solar cell to improve the formed solar cell efficiency.

### SUMMARY OF THE INVENTION

In light of the above, embodiments of the invention generally provide methods for forming a multilayer rear surface passivation layer on a solar cell substrate. The method includes forming a silicon oxide sub-layer having a net charge density of less than or equal to 2.1×10¹¹ Coulombs/cm² on a rear surface of a p-type doped region formed in a substrate comprising semiconductor material, the rear surface opposite a light receiving surface of the substrate and forming a silicon nitride sub-layer on the silicon oxide sub-layer.

Embodiments of the invention also include a solar cell device that may be manufactured according methods disclosed herein. The solar cell device includes a substrate comprising a semiconductor material where the substrate has a light receiving surface and a rear surface opposite the light receiving surface. The substrate also includes a multilayer rear surface passivation layer on the rear surface a p-type doped region formed in the substrate. The multilayer rear surface passivation layer includes a silicon oxide sub-layer having a net charge density of less than or equal to 2.1×10¹¹ Coulombs/cm² formed on the rear surface of the substrate and a silicon nitride sub-layer formed on the silicon oxide sub-layer. A back contact layer is formed on the multilayer rear surface passivation layer where the back contact layer includes a conductive material. A backside contact traverses the rear surface passivation layer to electrically couple the back contact layer with the semiconductor material.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1G depicts cross-sectional views of a portion of a substrate corresponding to various stages of the processes illustrated in FIG. 2.

FIG. 2 depicts a process flow diagram of a multilayer rear surface passivation layer formation process performed on a silicon substrate in accordance with embodiments of the invention.

FIG. 3 is a schematic side view of a parallel plate PECVD system that may be used to perform embodiments of the invention.

FIG. 4 is a top schematic view of one embodiment of a process system having a plurality of process chambers.

FIG. 5 is a graph showing the relationship between the effective surface recombination, open circuit voltage, and net amount of charge in the silicon oxide sub-layer formed according to embodiments of the invention.

FIG. 6 is a graph showing the relationship between the deposition rate, and the silicon-containing precursor flow rate when forming a silicon oxide sub-layer, and the refractive index of the silicon oxide sub-layer.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The invention generally provides methods of forming a multilayer rear surface passivation layer. The multilayer rear surface passivation layer formed by embodiments of the invention makes patterning and etching more easy for forming backside contacts and provides a hydrogen (H) source for bulk passivation of the substrate compared to conventional rear surface passivation layers, thereby forming a high efficiency solar cell device. In one embodiment, the methods include forming a silicon oxide sub-layer on a rear surface of a substrate and forming a silicon nitride-containing sub-layer, such as hydrogenated silicon nitride, on the silicon oxide sub-layer, followed by various patterning techniques for forming a backside contact layer on the multilayer rear surface passivation layer. Solar cell substrates that may benefit from the invention include substrates that have an active region that contains single crystal silicon, multi-crystalline silicon, polycrystalline silicon, and amorphous silicon, but may also be useful for substrates comprising germanium (Ge), gallium arsenide (GaAs), cadmium telluride (CdTe), cadmium sulfide (CdS), copper indium gallium selenide (CIGS), copper indium selenide (CuInSe₂), gallilium indium phosphide (GaInP₂), organic materials, as well as heterojunction cells, such as GaInP/GaAs/Ge or ZnSe/GaAs/Ge substrates, that are used to convert sunlight to electrical power.

In general, a rear surface passivation layer will have desirable optical properties to maximize light reflection and minimize absorption as light passes through the passivation layer. Additionally, the rear surface passivation layer will have desirable functional properties to “surface” passivate the surface(s) it is disposed over, “bulk” passivate the adjacent regions and surface of the substrate, and store positive charge in the passivation layer or “field” passivate. Thus, a passivation layer contains a desirable concentration of hydrogen to heal shallow defects found at the substrate surface, especially after firing of the substrate which drives H from the passivation layer to the surface of and into the substrate. The mechanism by which the passivation layer is able to perform these functions includes, for example, the ability of a formed passivation layer to be a source of hydrogen (H) that is used to correct defects in regions of the substrate, and the physical and/or chemical characteristics of the formed layer that are able to tie-up the dangling bonds at the substrate surface.

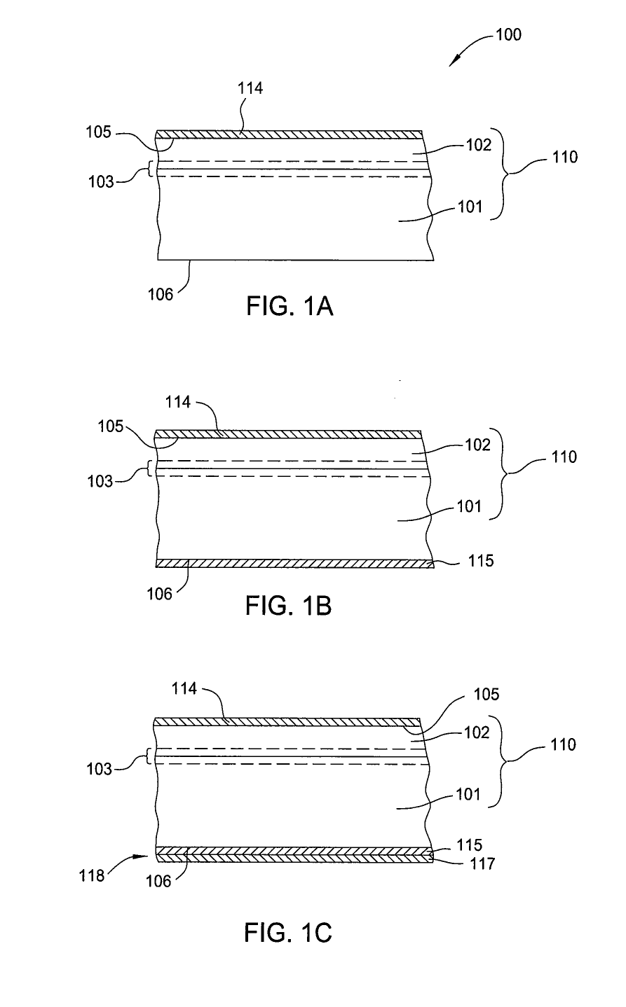

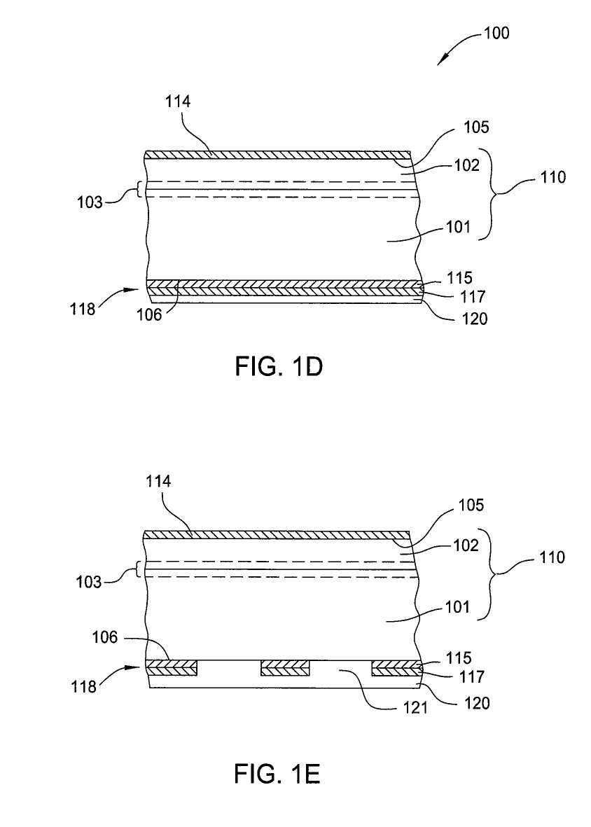

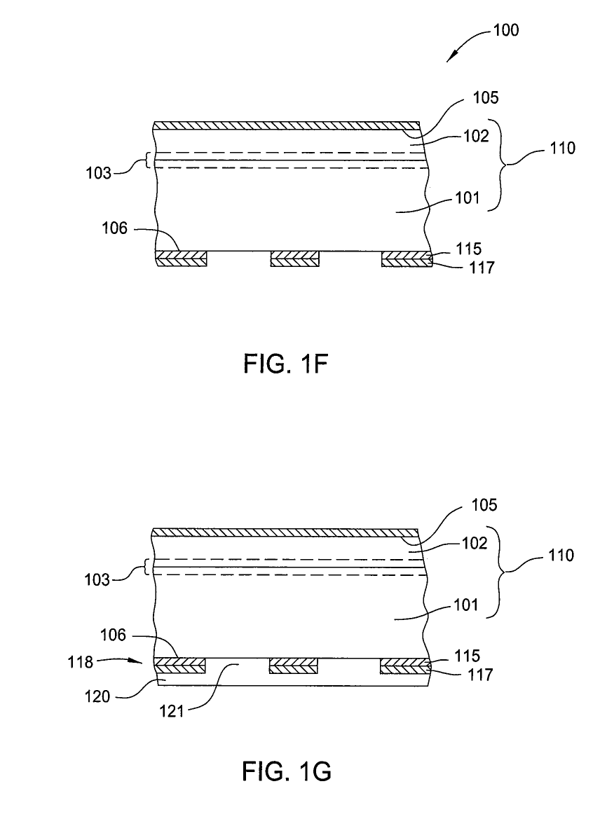

The solar efficiency can also be reduced, due to a reduction in the carrier lifetime caused by a shunt current created at the rear surface of the solar cell. The shunt current is created by a buildup of negative charge in the solar cell substrate 110 near the interface between the rear surface 106 of the solar cell substrate and dielectric/passivation layers 115/117 formed over the rear surface (see FIG. 1E). If sufficient negative charge builds up, due to the presence of an unwanted amount of positive charge in the dielectric layers, an inversion layer is created in the p-doped substrate 110, i.e. the population of electrons at the surface 106 exceeds the population of holes. The presence of the inversion layer can thus allow a shunt current to form, due to the leakage or migration of the electrons in the inversion layer to the backside contact layer 120. In other words, the buildup of negative charge at the interface leaks into the nearby rear contact regions, causing recombination to occur at the contact interface, thereby reducing the solar cell efficiency and lifetime. The rear surface passivation stack may be engineered to have a net charge density that prevents the inversion layer from forming at the interface, i.e. an insufficient amount of negative charge build up at the surface 106 of the p-type substrate, and thereby preventing a shunt current from forming at the rear surface of the solar cell.

Additionally, the multilayer rear surface passivation layer 118 can also act as a rear surface reflector that returns unabsorbed light back into the solar cell substrate 110 and thus improve the solar cell efficiency. In some configurations, the multilayer rear surface passivation layer 118 acts as a reflector at the rear surface of the solar cell. As light passes through the solar cell from the light receiving surface and through the light absorbing p-n junction region and towards the rear surface, unabsorbed light may be reflected back into the solar cell absorbing region. The unabsorbed light may reflect off the backside metal contacts and the interfaces between the backside metal contacts, sub-layers in the passivation layer, and silicon rear surface and back into the light absorbing layer, thereby improving solar cell efficiency. Additionally, rear surface dielectric/reflection coating layers may have a low wet etch rate ratio, thus preventing the via opening step from affecting the throughput. Therefore, there is a need for a passivation layer that has all of the above discussed properties.

Balancing the desired properties of a passivation layer for a solar cell is challenging without decreasing solar cell production throughput, especially when the passivation layer also functions as a reflective coating and as a charge holder. Various dielectric layers, such as silicon oxides, may be used as a rear surface reflective layer on the backside of a p-type crystalline silicon substrate. For example, silicon oxides such as silicon dioxide (SiO₂), help in reflecting infrared (IR) wavelengths back to the silicon for effective light trapping within the substrate.

Dielectric layers, such as silicon oxides, however, may not provide sufficient passivation due to limited H content in the film when formed using conventional methods. Moreover, conventional methods of forming PECVD silicon oxides have lower deposition rates, e.g. around 350 Å per minute and do not provide a charge source sufficient to prevent or minimize shunt current formation in the adjacent rear surface of the solar cell device. Therefore, in one embodiment, the high quality rear surface passivation layer may comprise one or more layers that have differing compositions, differing physical properties, or differing electrical properties to provide a desired passivating effect and optical properties. Additionally, embodiments of the invention provide a multilayer rear surface passivation layer that is tailored for etch gel patterning or laser fired formation of backside contacts. Embodiments of the invention provide a less dense, easier to process rear surface passivation film stack forming a dielectric mirror to reflect light passing through the solar cell back into the light absorbing portion of the substrate.

### Passivation Layer Formation Process

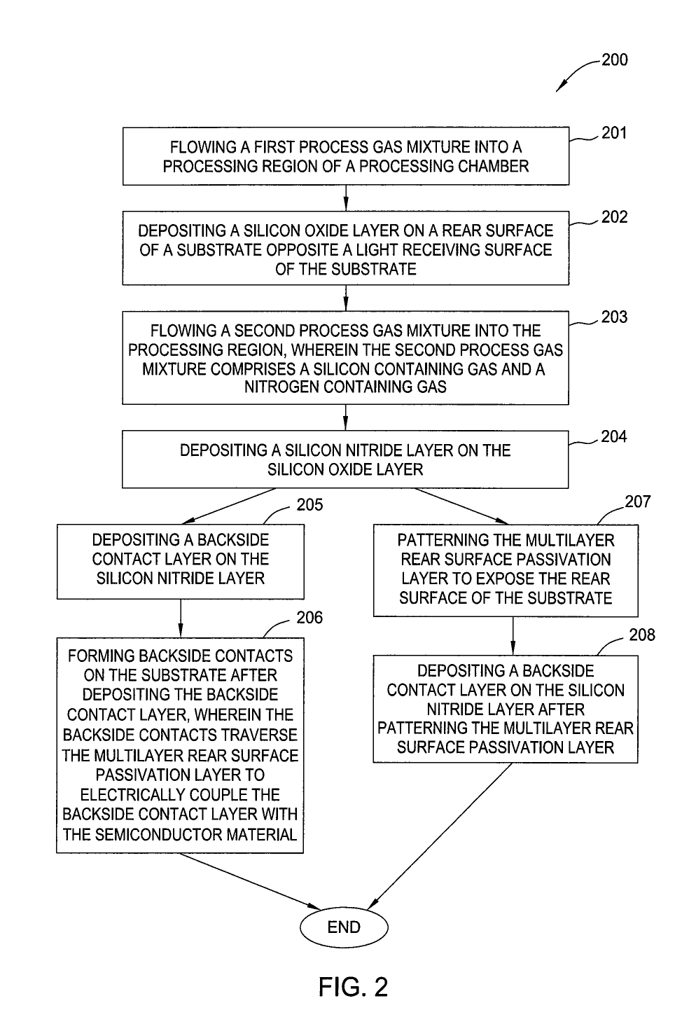

FIGS. 1A-1G illustrate schematic cross-sectional views of a solar cell substrate 110 during different stages in a processing sequence used to form a multilayer rear surface passivation layer 118 on a rear surface 106 of a solar cell device 100. FIG. 2 illustrates a method 200 used to form the passivation layer on a solar cell substrate 110. The sequences found in FIG. 1 correspond to the stages depicted in FIGS. 1A-1G, which are discussed herein. In one embodiment of the solar cell device 100, the base region 101 comprises a p-type crystalline silicon substrate 110 having a bottom or rear surface 106, and the emitter region 102 comprises an n-type layer formed in the silicon over the base region 101. The p-type dopant concentration may be anywhere from p⁻ to p⁺ concentration, such as between 10¹⁵ to 10²¹ atoms per cm³. While the discussion below primarily discusses a method and apparatus for processing a substrate having a n-type emitter region formed over a p-type base region this configuration is not intended to limit the scope of the invention described herein, since the multilayer rear surface passivation layer 118 could also be formed on a rear surface of a n-type base region solar cell configuration.

In another embodiment of the invention, a solar cell device 100 is provided. The solar cell device 100 includes a substrate 110 comprising a semiconductor material, such as silicon, and has a light receiving surface, such as front surface 105, and a rear surface 106 opposite the light receiving surface. An anti-reflective coating may be deposited over the light receiving surface, such as passivation—ARC layer 114. The solar cell also includes a multilayer rear surface passivation layer 118 that includes a silicon oxide sub-layer 115 formed on the rear surface 106 of a p-type doped region, such as base 101 formed in the substrate 110, and a silicon nitride sub-layer 117, formed on the silicon oxide sub-layer 115 of the substrate 110. The silicon oxide sub-layer has a net charge density of less than or equal to 2.1×10¹¹ Coulombs/cm² The solar cell device 100 also has a backside contact layer 120 comprising a conductive material that is formed on the multilayer rear surface passivation layer 118. Backside contacts 121 traverse the multilayer rear surface passivation layer 118 to electrically couple the backside contact layer 120 with the semiconductor material of the substrate 110. Various methods of forming a solar cell device 100 are discussed below.

FIG. 1A schematically illustrates a cross-sectional view of an at least partially formed silicon solar cell device 100 that comprises a substrate 110. The substrate 110 includes a base region 101, an emitter region 102, and a p-n junction region 103. The p-n junction region 103 is disposed between base region 101 and emitter region 102 of the solar cell, and is the region in which electron-hole pairs are generated when solar cell device 100 is illuminated by incident photons of light. A passivation-ARC layer 114 is formed on the front surface 105 of solar cell device 100.

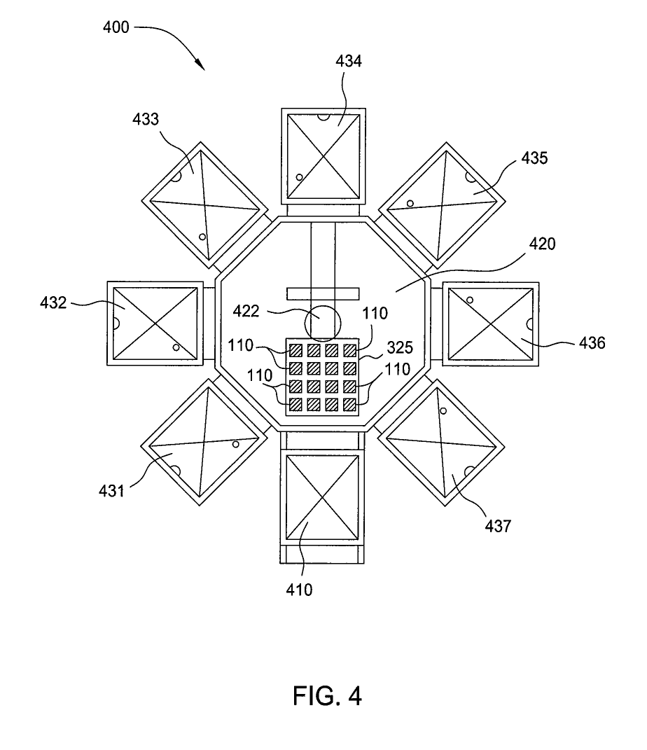

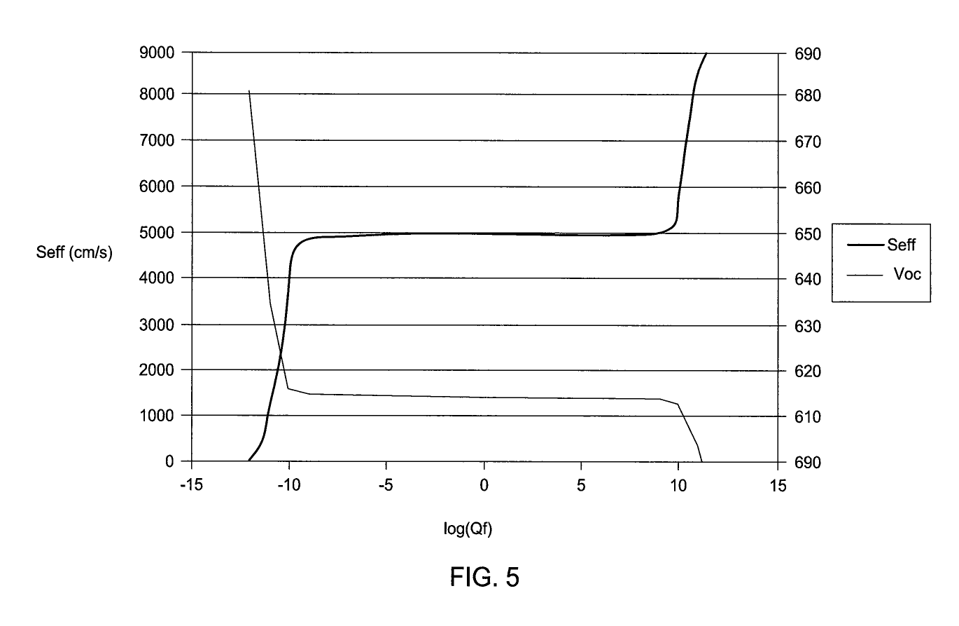

In one embodiment, the method of forming a multilayer rear surface passivation layer 118 includes forming a silicon oxide (sometimes represented as SiₓO_{y} or SiₓO_{y}:H) sub-layer 115 on the rear surface 106 of the substrate 110 followed by forming a silicon nitride (sometimes represented as SiₓN_{y} or SiₓN_{y}:H) sub-layer 117 on the silicon oxide sub-layer 115. The silicon nitride sub-layer 117 may be less dense (less than 2.7 g/m²) compared to typical silicon nitride sub-layers used for interface passivation (above 2.7 g/cm³). The silicon nitride-containing layer may be a hydrogenated silicon nitride. In one embodiment, the silicon oxide sub-layer 115 and the silicon nitride sub-layer 117 are formed on the rear surface 106 using a chemical vapor deposition technique, such as plasma enhanced chemical vapor deposition (PECVD), and may be formed in a chamber in-situ to reduce production times. In another embodiment, the silicon oxide sub-layer and silicon nitride sub-layer are formed using a physical vapor deposition (PVD) technique. An example of multilayer rear surface passivation layer 118 formation process is further described below in conjunction with FIGS. 4 and 5, which illustrate one example of a cluster tool having various chambers which may execute various embodiments of the invention.

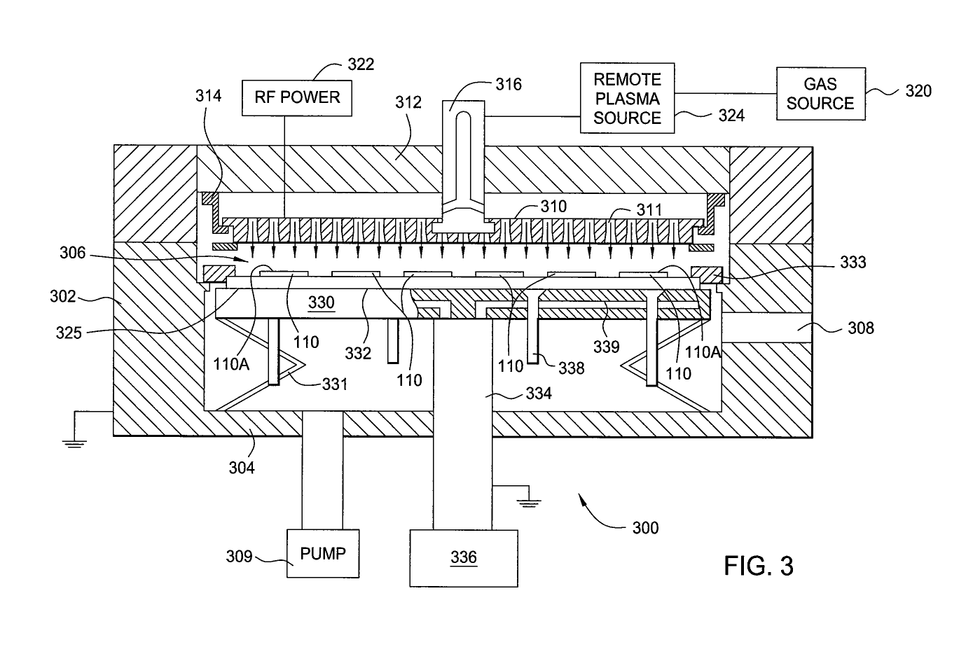

Referring to FIG. 2, in one embodiment, the method 200 used to form the multilayer rear surface passivation layer 118 on a solar cell substrate 110 generally begins at process 201. The processes performed at process 201-204 may be performed in a single process performed in one substrate processing chamber, or in multiple separate processes performed in one or more substrate processing chambers. An example of processing chambers is further described below in conjunction with FIGS. 3 and 4. One will note that, in some cases, it may be desirable to assure that the substrate is not exposed to oxygen for extended periods of time. Therefore, in some embodiments of the invention, it is desirable to perform each of the processes 202-208 in an oxygen-free inert and/or vacuum environment, such as in the vacuum processing regions of a cluster tool, or system 400 (FIG. 5), so that the substrate is not exposed to oxygen between the processes.

After disposing one or more of the substrates 110 in a processing chamber, such as chamber 300 in FIG. 4, the substrates 110 are processed according to embodiments of the invention. At process 201, the method includes flowing a first process gas mixture into a process volume 306 of a processing chamber formed on the surfaces of the substrate. A plasma is generated in the process volume 306 and a silicon oxide sub-layer 115 is deposited on a rear surface 106 of a substrate 110 opposite a light receiving surface, such as front surface 105, of the substrate (FIG. 1B), as shown in process 202. In one embodiment the silicon oxide sub-layer 115 is silicon dioxide (SiO₂).

The first process gas mixture may include a silicon-containing gas and an oxidizing gas. The silicon-containing gas may be selected from a group consisting of silane, disilane, chlorosilane, dichlorosilane, trichlorosilane, dibromosilane, trimethylsilane, tetramethylsilane, tridimethylaminosilane (TriDMAS), tetraethoxysilane (TEOS), triethoxyfluorosilane (TEFS), silicon tetrachloride, silicon tetrabromide, 1,3,5,7-tetramethylcyclotetrasiloxane (TMCTS), dimethyldiethoxy silane (DMDE), octomethylcyclotetrasiloxane (OMCTS), methyldiethoxysilane (MDEOS), bis(tertiary-butylamino)silane (BTBAS), or combinations thereof. The oxidizing gas may be selected from the group consisting of consisting of oxygen (O₂), nitrous oxide (N₂O), ozone (O₃), and combinations thereof. The ratio of the oxidizing gas to the silicon-containing gas may be from about 5:1 to about 10:1, such as about 6:1. The high degree of oxidant to silicon-containing gas ratio, such as TEOS gas, helps expand the process window, thereby making the process more reliable. In one embodiment the silicon oxide sub-layer 115 is deposited at 2,000 angstroms (Å) or more per minute, such as about 3,000 Å/min, and at a temperature between about 100° C. and 200° C. The silicon oxide sub-layer 115 may have a thickness between about 500 Å and 1,000 Å. In one embodiment, the silicon oxide sub-layer 115 is 750 Å. The formed silicon oxide sub-layer 115 has a refractive index (n) between 1.45 and 1.47.

In one embodiment, the sum of the total amount of the trapped positive charge found in the silicon oxide sub-layer 115 has enough trapped charge to achieve a charge density of about 2.1×10¹¹ Coulombs/cm² or less, such as between about −1×10¹⁰ Coulombs/cm² and about 2.0×10¹¹ Coulombs/cm². FIG. 5 is a graph showing the relationship between the effective surface recombination, open circuit voltage, and net amount of charge in the silicon oxide sub-layer formed according to embodiments of the invention.

The left hand y-axis shows the effective surface recombination rate (Seff) in cm/s of a silicon oxide film that may be formed according to embodiments of the invention. The right hand y-axis shows the open circuit voltage (Voc) of a solar cell device having a silicon oxide film that may be formed according to embodiments of the invention. The x-axis shows the net amount of charge density (log Qf) in a silicon oxide film formed that may be formed according to embodiments of the invention. As the amount of charge decreases from about 2.1×10¹¹ Coulombs/cm², the effective surface recombination decreases, and the open circuit voltage increases. PECVD deposited silicon oxides using conventional methods have a higher net amount of charge, e.g. greater than 5.0×10¹¹ Coulombs/cm², thereby inducing formation of a shunt current in the rear surface of the solar cell device.

It is desirable to have a high Voc and a low Seff in a solar cell device. As FIG. 5 illustrates, a solar cell device having a rear surface passivation layer including a silicon oxide layer formed according to embodiments of the invention achieve a higher Voc and lower Seff when compared to conventionally PECVD deposited silicon oxides. It is believed that this desirable combination of Voc and Seff is due to the net charge amount that is equal to or less than 2.1×10¹¹ Coulombs/cm². Thus, one method of forming a multilayer rear surface passivation layer 118 on a solar cell substrate 110 includes forming a silicon oxide sub-layer 115 having a net charge density of less than or equal to 2.1×10¹¹ Coulombs/cm² on a rear surface 106 of a p-type doped region, such as base region 101, formed in the substrate 110 comprising semiconductor material, the rear surface 106 opposite a light receiving surface 105 of the substrate, and forming a silicon nitride sub-layer 117 on the silicon oxide sub-layer 115.

It should be noted that the lack of a negative sign in front of the desired charge density number is only intended to signify that the net charge amount of the silicon oxide sub-layer is positive versus negative. Thus, as shown in FIG. 5, a log(Qf) of zero indicates no net charge, and the negative numbers along the x-axis indicate a net amount of negative charge in the silicon oxide sub-layer. In cases where the silicon oxide sub-layer 115 and the silicon nitride sub-layer 117 each contain positive and negative charges, the charge values discussed herein are the net values of charge, or the sum of the absolute value of the total amount of positive charge minus the absolute value of the total amount of negative charge taken in each respective layer. Generally, the lower net amount of positive charge or alternatively the higher the net amount of negative charge in the silicon oxide sub-layer on the rear surface of the solar cell device, the greater the lifetime of the solar cell and the lower the SRV.

The method 200 further includes flowing a second process gas mixture into the process volume, wherein the second process gas mixture comprises a silicon-containing gas and a nitrogen-containing gas at process 203. A plasma is generated in the process volume 306, and a silicon nitride sub-layer 117 is deposited on the silicon oxide sub-layer 115, at process 204. Together, the silicon oxide sub-layer 115 and silicon nitride sub-layer 117 form the multilayer rear surface passivation layer 118 (FIG. 2C). In one embodiment, the silicon nitride sub-layer is deposited at more than 1,000 Å per minute and at a temperature between about 250° C. and 200° C. In one embodiment, the silicon nitride sub-layer has a thickness between about 250 Å and 1000 Å. In another embodiment, the silicon nitride sub-layer has a thickness between about 400 Å and 1000 Å. The sum of the total amount of the trapped positive charge found in the silicon nitride sub-layer 117 has a charge density of about 3.0×10¹² Coulombs/cm² or less.

The multilayer rear surface passivation layer 118 may have a total thickness between about 1,000 Å and 1,500 Å. For example, the silicon oxide sub-layer 115 may be 750 Å thick and the silicon nitride sub-layer 117 may be 400 Å thick, giving a total multilayer rear surface passivation layer 118 thickness of 1,150 Å. In one embodiment, the silicon oxide sub-layer 115 is 750 Å thick and the silicon nitride sub-layer is 500 Å thick, yielding a total multilayer passivation layer thickness of 1,250 Å. A person of ordinary skill may use various other combinations to achieve a total thickness between 1,000 Å and 1,500 Å as desired for the solar cell.

In one embodiment, the silicon oxide sub-layer may be 750 Å thick, and only the silicon nitride sub-layer thickness is increased in an amount necessary to reach a desired total multilayer passivation layer thickness. Thus, when the silicon oxide sub-layer is 750 Å thick, the silicon nitride sub-layer may be between 400 Å-1000 Å thick.

The silicon-containing gas of the second process gas mixture may be selected from the group consisting of silane, disilane, chlorosilane, dichlorosilane, trichlorosilane, dibromosilane, trimethylsilane, tetramethylsilane, tridimethylaminosilane (TriDMAS), tetraethoxysilane (TEOS), triethoxyfluorosilane (TEFS), silicon tetrachloride, silicon tetrabromide, 1,3,5,7-tetramethylcyclotetrasiloxane (TMCTS), dimethyldiethoxy silane (DMDE), octomethylcyclotetrasiloxane (OMCTS), methyldiethoxysilane (MDEOS), bis(tertiary-butylamino)silane (BTBAS), or combinations thereof. The nitrogen-containing gas of the second process gas mixture may be selected from the group consisting of ammonia (NH₃), nitrogen (N₂), or combinations thereof. The ratio of the silicon-containing gas to the nitrogen-containing gas in the second gas mixture may be between about 5:1 to about 15:1, such as about 7:1. The nitrogen-containing gas in the ratio is the total amount of nitrogen-containing gas or gases in the gas mixture. The ratio of silicon-containing gas to nitrogen-containing gas may help determine the stoichiometry and film properties of the silicon nitride sub-layer.

The formed silicon nitride sub-layer 117 has a low density, a high H atomic %, a high N—H bond to Si—H bond ratio, a refractive index (n) between 1.9 and 2.2, and a light absorption coefficient (k) near zero. A high ratio of N-H/Si—H bonds may help to improve passivation of the local interfaces because the N—H bonds are more prone to losing their hydrogen during processing. Typically, SiO₂ is comparatively easy to etch through using HF, and is the standard when measuring wet etch rate, sometimes referred to as wet etch rate ratio or WERR. The wet etch of a material is compared to the wet etch rate of thermal SiO₂ using 1% HF solution to give you a WERR of the material. The closer you get to a WERR of thermal SiO₂, the easier it is to etch the material with an etch gel. Etch gels conventionally have HF, NH₄F, or other salts of the fluoride ion as the main etching agent, though it may be in a slurry of other constituent chemical compounds. Silicon nitride is typically difficult to etch, having a low WERR, sometimes even approaching 10× slower than the WERR of SiO₂. However, by forming a silicon nitride having a low density and high H composition, the WERR of the silicon nitride approaches that of SiO₂, thereby increasing the WERR of silicon nitride. The WERR of the silicon nitride sub-layer formed according to embodiments of the invention may be less than or equal to 5.0.

One purpose of the etch gel is to open up the solar cell backside layers to form vias when making backside contacts with the substrate to electrically connect the substrate with a back contact layer. For example, one way to etch through the backside layers is to use a paste that has an etchant when you screen print the backside for forming a backside contact layer. Another method is to etch through the nitride and oxide layers to make vias and then fill the vias with a paste or by a PVD metal deposition to form the backside contacts. Another method of patterning the backside layers is to use laser forming methods, such as by forming laser-fired contacts (LFC). The backside layers, such as the multilayer rear surface passivation layer 118 formed according to embodiments of the invention, are easier to pattern regardless of the method of patterning because of the combined physical and chemical properties of the oxide and nitride layers. Such layers are easier to etch through and to shoot through with a laser when patterning the backside layers, as will be discussed in greater detail below.

In one embodiment, as schematically illustrated in FIGS. 2D-2E, and FIG. 3, a backside contact layer 120 is deposited on the silicon nitride sub-layer 117, as in process 205. The backside contacts 121 are then formed on the substrate 110 after depositing the backside contact layer, where the backside contacts 121 traverse the multilayer rear surface passivation layer 118 to electrically couple the backside contact layer 120 with the semiconductor material of the substrate 110, as in process 206. The backside contact layer 120 is a conductive material such as aluminum, silver, nickel, alloys thereof, combinations thereof, and any other conductive material compatible with solar cell technology. The backside contact layer 120 may be deposited using a PVD process, an electroless deposition process, or other conductive material deposition processes. Backside contacts 121 may be formed using, for example, a laser firing process or a screen printing process. In the screen printing process, an aluminum paste is printed through a screen followed by a high temperature step to form the backside contacts 121.

In another embodiment, after depositing the silicon nitride sub-layer in process 204, the multilayer rear surface passivation layer 118 is patterned to expose the rear surface 106 of the substrate 110, as illustrated in FIG. 2F. The silicon oxide 115 and silicon nitride 117 sub-layers may be patterned using wet or dry etching techniques known in the art. The backside contacts 121 are then formed by depositing a backside contact layer 120 on the silicon nitride sub-layer 117 after patterning the multilayer rear surface passivation layer 118 as shown in process 208 of FIG. 3. The backside contact layer may comprise similar conductive materials and formed using similar methods as previously discussed with respect to processes 205 and 206.

During a firing or annealing process performed on the substrate after deposition of the multilayer rear surface passivation layer 118, the hydrogen in the silicon nitride sub-layer will be driven into the substrate 110 to also provide bulk passivation of the substrate 110. Additionally, some of the hydrogen will pass through the silicon oxide sub-layer 115 and passivate the interface between the silicon oxide and the rear surface 106 of the substrate 110. The reservoir of hydrogen in the silicon nitride sub-layer 117 can be driven to the substrate and rear surface of the silicon substrate for passivating any vacancies or crystalline defects in the substrate structure. A solar cell formed according to embodiments of the invention may have an increased Quantum efficiency of 0.5-1.0%. The lower deposition temperatures provide generally higher deposition rates. The reflection rate may be as high as 95% compared to approximately 65% or less of a “standard cell” having only a metal back contact layer.

### Hardware Configuration

FIG. 4 is a schematic cross-section view of one embodiment of a plasma enhanced chemical vapor deposition (PECVD) chamber 300 in which one or more of the processes illustrated and discussed in conjunction with FIG. 3 may be performed. A similarly configured plasma enhanced chemical vapor deposition chamber is available from Applied Materials, Inc., located in Santa Clara, Calif. It is contemplated that other deposition chambers, including those from other manufacturers, may be utilized to practice the present invention.

It is believed that the plasma processing configuration provided in the processing chamber 300 has significant advantages over other prior art configurations when used to perform one or more of the processes described in FIG. 3. In one embodiment, the PECVD chamber 300 is configured to process a plurality of substrates at one time. In one embodiment, PECVD processing chamber 300 is adapted to simultaneously process a plurality of substrates that are arranged in a planar array arrangement (FIG. 5), as opposed to processing vertical stacks of substrates (e.g., batches of substrates stacked in cassettes). Processing the batches of substrates arranged in a planar array allows each of the substrates in the batch to be directly and uniformly exposed to the generated plasma, radiant heat, and/or processing gases. Therefore, each substrate in the planar array is similarly processed in the process volume of a processing chamber, and thus does not rely on diffusion type processes and/or the serial transfer of energy to all substrates in a conventionally configured batch that is being processed, such as a stacked or back-to-back configured batch of substrates commonly found in the prior art.

In one configuration, the PECVD chamber 300 is adapted to accept a substrate carrier 325 (FIGS. 4 and 5) that is configured to hold a batch of substrates during the transferring and processing of the substrates. In one embodiment, the substrate carrier 325 has a surface area of about 10,000 cm² or more, such as about 40,000 cm² or more, or about 55,000 cm² or more, that is configured to support a planar array of substrates disposed thereon during processing. In one embodiment, the substrate carrier 325 has a plurality of recesses (not shown) formed therein that are adapted to hold between about 4 and about 49 solar cell substrates that are 156 mm×156 mm×0.3 mm in size in a face-up or face-down configuration. The substrate carrier 325 may be formed from a ceramic (e.g., silicon carbide, alumina), graphite, metal or other suitable material. In one configuration, a batch of solar cell substrates are simultaneously transferred in a vacuum or inert environment (e.g., transfer chamber 420 in FIG. 5) on the substrate carrier 325, between a plurality of processing chambers to reduce the chance of contamination and improve substrate throughput over other prior art configurations.

The chamber 300 generally includes walls 302, a bottom 304, and a showerhead 310, and substrate support 330 which define a process volume 306. The process volume is accessed through a valve 308 such that the substrates disposed on the substrate carrier 325, may be transferred in and out of the chamber 300. The substrate support 330 includes a substrate receiving surface 332 for supporting a substrate and stem 334 coupled to a lift system 336 to raise and lower the substrate support 330. A shadow frame 333 may be optionally placed over periphery of the substrate carrier 325. Lift pins 338 are moveably disposed through the substrate support 330 to move the substrate carrier 325 to and from the substrate receiving surface 332. The substrate support 330 may also include embedded heating and/or cooling elements 339 to maintain the substrate support 330 at a desired temperature. The substrate support 330 may also include grounding straps 331 to provide RF grounding at the periphery of the substrate support 330. Examples of grounding straps are disclosed in U.S. Pat. No. 6,024,044 issued on Feb. 15, 1000 to Law et al. and U.S. patent application Ser. No. 11/613,934 filed on Dec. 20, 1006 to Park et al., which are both incorporated by reference in their entirety to the extent not inconsistent with the present disclosure. In one embodiment, the substrate support 330 has an RF source (not shown) that is coupled to an electrode (not shown) that is embedded in the substrate support 330 so that an RF bias can be applied to the substrates 110 disposed over the substrate support 330.

The showerhead 310 is coupled to a backing plate 312 at its periphery by a suspension 314. The showerhead 310 may also be coupled to the backing plate by one or more center supports 316 to help prevent sag and/or control the straightness/curvature of the showerhead 310. A gas source 320 is coupled to the backing plate 312 to provide gas through the backing plate 312 and through the passages 311 of showerhead 310 to the substrate receiving surface 332. A vacuum pump 309 is coupled to the chamber 300 to control the process volume 306 at a desired pressure. An RF power source 322 is coupled to the backing plate 312 and/or to the showerhead 310 to provide RF power to the showerhead 310 so that an electric field is created between the showerhead and the substrate support so that a capacitively coupled plasma may be generated using the gases disposed between the showerhead 310 and the substrate support 330. Various RF frequencies may be used, such as a frequency between about 0.3 MHz and about 100 MHz. In one embodiment the RF power source is provided at a frequency of 13.56 MHz. Examples of showerheads are disclosed in U.S. Pat. No. 6,477,980 issued on Nov. 12, 1002 to White et al., U.S. Publication 10050251990 published on Nov. 17, 1006 to Choi et al., and U.S. Publication 1006/0060138 published on Mar. 23, 1006 to Keller et al.

It is believed that the direct contact of the capacitively coupled plasma to the processing surface 110A (FIG. 4) of the substrates 110 has advantages over designs that do not directly expose all of the substrates to the plasma, due to the ability of the chamber 300 configuration to provide energetic and/or ionized species directly to all parts of the processing surface 110A during processing. The degree of plasma interaction applied to the complete processing surface 110A can be directly controlled in the chamber 300 by adjusting the RF power delivered to the showerhead 310, the chamber pressure during processing, and/or the bias applied to the substrate support 330. Typical non-direct exposure type chamber configurations include remotely driven plasma configurations or other stacked substrate configurations that rely on the diffusion of the generated plasma to one or more of the substrates, or parts of each of the substrates, during processing.

However, in some embodiments, a remote plasma source 324, such as an inductively coupled remote plasma source, may also be coupled between the gas source and the backing plate. In one process configuration, a cleaning gas may be provided to the remote plasma source 324 between processing substrates, so that a remote plasma is generated and provided to clean chamber components. The cleaning gas may be further excited by the RF power source 322 provided to the showerhead. Suitable cleaning gases include, but are not limited to, NF₃, F₂, and SF₆. Examples of remote plasma sources are disclosed in U.S. Pat. No. 5,788,778 issued Aug. 4, 1998 to Shang et al.

In one embodiment, the heating and/or cooling elements 339 may be set to provide a substrate support temperature during deposition of about 300° C. or less, such as between about 100° C. and about 300° C. or between about 150° C. and about 200° C., such as about 100° C. The spacing during deposition between the front surface of a substrate disposed on a substrate carrier 325 disposed on the substrate receiving surface 332 and the showerhead 310 may be between 400 mil and about 1,100 mil, such as between 1,000 mil and about 1,050 mil. For example, the spacing during deposition of the silicon oxide sub-layer 115 may be about 1,100 mil and about 1,050 mil during deposition of the silicon nitride sub-layer 117. Inventors: please provide spacing parameters.

FIG. 4 is a top schematic view of one embodiment of a process system 400 having a plurality of process chambers 431-437, such as PECVD chambers chamber 300 of FIG. 4 or other suitable chambers capable of performing the processes described in conjunction with FIG. 3. The process system 400 includes a transfer chamber 420 coupled to a load lock chamber 410 and the process chambers 431-437. The load lock chamber 410 allows substrates to be transferred between the ambient environment outside the system and vacuum environment within the transfer chamber 420 and process chambers 431-437. The load lock chamber 410 includes one or more evacuatable regions that is configured to hold one or more substrate carriers 325 that are configured to support a plurality of substrates 110. The evacuatable regions are pumped down during the input of the substrates into the system 400 and are vented during the output of the substrates from the system 400. The transfer chamber 420 has at least one vacuum robot 422 disposed therein that is adapted to transfer the substrate carriers 325 and substrates between the load lock chamber 410 and the process chambers 431-437. Seven process chambers are shown in FIG. 5; however, the system 400 may have any suitable number of process chambers.

In one embodiment of system 400, a first process chamber 431 is configured to perform process 201, a second process chamber 432 is configured to perform processes 202-206, a third process chamber 433 is configured to perform processes 207-208, and a fourth process chamber 434 is configured to perform process 209 or 210 on the substrates. Other embodiments may use various combinations of the processing chambers 431-437 of system 400 to perform processes 201-204 or even 201-208. In yet another embodiment of system 400, at least one of the process chambers 431-437 is configured to perform most of the processes, such as 201-204, on the substrates.

### Passivation Layer Formation Processes

Referring back to FIG. 3, during one phase of the method 200 the surfaces of the substrate 110 are subjected to a plurality of processes that are used to form the silicon oxide sub-layer 115 and the silicon nitride sub-layer 117 on the rear surface 106 of the substrate. The following are illustrative examples of processes 201-204 that may be performed in a processing chamber similar to processing chamber 300, which is discussed above. The processes described below generally include methods of preparing a rear surface of a substrate using primarily dry processing techniques performed in one or more process chambers (e.g., processing chamber 300) found in one or more cluster tools, such as system 400. In one embodiment, all of the processes performed in the method 200 are performed in one or more of the processing chambers 431-437 found in one or more system 400. One will note that the hardware configurations illustrated in FIGS. 4 and 5 are not intended to be limiting as to the scope of the invention described herein.

In one embodiment, a batch of substrates 110 is disposed on a substrate carrier 325 and positioned in a processing chamber so that processes 201-204 can be performed on the substrates. In one embodiment, the substrates are exposed to a first process gas mixture and RF plasma to form a silicon oxide sub-layer 115 on the exposed rear surfaces 106 of the substrates 110. In one example, the substrate is exposed to a 13.56 MHz RF plasma that contains an amount of gas precursors in the first gas mixture that is used to form a silicon oxide sub-layer as the first layer of the multilayer rear surface passivation film on a solar cell.

In one embodiment, the first gas mixture may comprise silicon-containing precursors such as silane type gases, siloxane type gases, or combinations thereof, and an oxidizing gas as discussed previously. Gases that are optionally introduced into the chamber at the same time as the silicon-containing precursors include carrier gases, such as helium, nitrogen, oxygen, nitrous oxide, and argon. In one example, the silicon oxide sub-layer is formed by, first, delivering a silicon-containing precursor, an oxidizing precursor, and a carrier gas (e.g., helium) into the chamber at a desired flow rate to achieve a chamber pressure of about 1.5 Torr. The flow rate of the silicon-containing precursor may be between about 1,800 to about 2,200 standard cubic centimeters (sccm). The oxidizing gas flow rate may be between about 13,500 sccm to about 16,500 sccm. Alternatively, the flow rates may be normalized to a flow rate per substrate surface area (sccm per cm²). For example, 56 substrates may be processed and have a combined surface area of 1,200 mm×1,300 mm (15,600 cm²). Thus, the silicon-containing precursor flow rate may be between about 0.115 and about 0.141 sccm per cm² while the oxidizing gas flow rate may be between about 0.865 to about 1.10 sccm per cm² for depositing the silicon oxide sub-layer 115. The ratio of the flow rate of the oxidizing precursor (e.g., N₂O) to the flow rate of the silicon-containing precursor (e.g., TEOS) into the chamber is from about 5:1 to about 10:1, for example about 6:1. In one embodiment, the oxidizing precursor flow rate is about 80 sccm per liter of process volume and the silicon-containing precursor flow rate is about 20 sccm per liter of process volume.

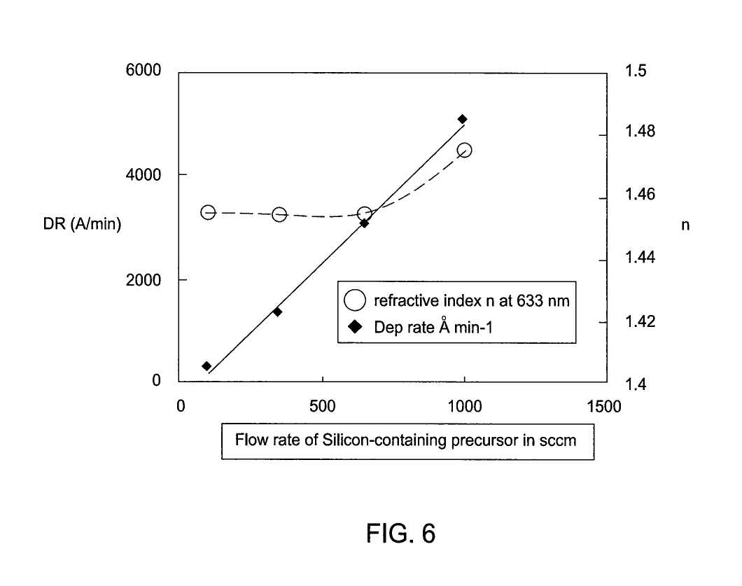

FIG. 6 is a graph showing the relationship between the deposition rate, and the silicon-containing precursor flow rate when forming a silicon oxide sub-layer, and the refractive index of the silicon oxide sub-layer. The left-hand y-axis shows the deposition rate of a silicon oxide sub-layer 115, and the x-axis shows the flow rate (sccm) of the silicon-containing precursor used for forming the silicon oxide sub-layer. The refractive index (n) of the deposited silicon oxide sub-layer is shown along the right hand y-axis. As the graph shows, the deposition rate of the silicon oxide sub-layer 115 increases as the flow rate of the silicon-containing precursor increases without significant change in the refractive index, but only up to a certain point.

Increasing the silicon-containing precursor flow rate beyond approximately 650 sccm for this example sharply increases the refractive index of the deposited silicon oxide layer. It is believed that the sharp increase in the refractive index is due to a silicon rich and/or hydrogen rich deposited silicon oxide film. Based on this data, going beyond the 5:1 ratio of oxygen-containing gas to silicon-containing gas in the gas mixture would generally make the film silicon and/or hydrogen rich, resulting in an undesired increase in the refractive index of the formed silicon oxide film.

A lower refractive index is preferable, however, for the backside passivation layers. Thus, according to embodiments of the invention, the deposition rate can be increase to as high as 3,000 Å per minute without adversely affecting the refractive index of the deposited silicon oxide sub-layer. In some embodiments, however, where silicon-containing precursors already have Si—O bonds present, such as TEOS, OMCTS, and the like, the amount of oxygen-containing gas used for forming the silicon oxide sub-layer may be even lower without incurring the negative effects of an increased refraction index. Thus, the ratio of oxygen-containing gas to silicon-containing gas where the silicon precursors have Si—O bonds could be as low as 1:1. When the gas mixture ratios approach 1:1, however, the organic portion of the oxygen-containing gas may be retained in the silicon oxide film as the silicon oxide film is deposited. Thus, an extra process may be necessary to remove any organic residues retained in the silicon oxide film during deposition.

In one embodiment, the temperature of a substrate support 330 positioned in the process chamber 300 may be from 100° C. to 450° C., such as from 380 to 390° C. The silicon-containing precursor and the oxidizing precursor may be delivered into the chamber for a period of time sufficient to deposit a silicon oxide sub-layer having a thickness of between about 500 Å and about 1,000 Å. The plasma may be provided by RF power from about 300 mW/cm² to about 1.2 W/cm², such as about 0.5 W/cm², at a frequency of 13.56 MHz. The RF power density for the silicon oxide sub-layer deposition may generate a plasma for a period of time of about 20 seconds. The RF power may be provided to the showerhead 310 and/or a substrate support 330. The silicon oxide sub-layer 115 may be deposited at a rate greater than 2,000 Å per minute, for example at 3,000 Å per minute. In some conventional methods, the silicon oxide for solar cell passivation is formed at only 350 Å per minute. Thus, the silicon oxide sub-layer may be formed almost ten times faster than conventional methods. The silicon oxide sub-layer has a hydrogen concentration of between about 1 atomic percent (at. %) and 5 at. %, such as between about 2 to about 3 at %.

Next, at processes 203-204, the substrate is exposed to a reactive gas containing RF plasma that is used to form a silicon nitride sub-layer 117 on the silicon oxide sub-layer 115 formed on the rear surface 106 of substrates 110. The second process gas mixture may comprise a silicon-containing gas, a nitrogen-containing gas, and a hydrogen gas (H₂) diluent. The second process gas mixture may be a combination of silane (SIH₄) and nitrogen (N₂), silane and ammonia (NH₃), or silane, ammonia, and nitrogen.

In one example, the flow rate of the silicon-containing precursor may be the same flow rates used for depositing the silicon oxide sub-layer. The nitrogen-containing gas flow rate may be between about 15,570 sccm to about 19,030 sccm. Alternatively, the flow rates may be normalized to a flow rate per substrate surface area (sccm per cm²). Thus, using the same substrate area as above, the silicon-containing precursor flow rate may be between about 0.115 and about 0.141 sccm per cm² while the nitrogen-containing gas flow rate may be between about 0.998 and about 1.22 sccm per cm² for depositing the silicon nitride sub-layer 117. The ratio of the flow rate of the nitrogen-containing precursor (e.g., N₂) to the flow rate of the silicon-containing gas (e.g., TEOS) into the chamber is about 5:1 to about 15:1, such as about 7:1.

In another example, flow rates for a second process gas mixture containing silane, ammonia, and nitrogen may be 20 sccm, 60 sccm, and 60 sccm, per liter of chamber volume, respectively. Flow rates for a process gas mixture containing silane, ammonia, nitrogen, and hydrogen may be 20 sccm, 20 sccm, 60 sccm, and 60 sccm, per liter of chamber volume, respectively. The nitrogen to silane ratio may be about 3 and the ammonia to silane ratio may be about 3. The substrate support 330 temperature is generally maintained at a temperature of about 350° C. to 450° C. during this process.

A plasma is generated in the processing chamber to deposit a silicon nitride sub-layer 117 on the silicon oxide sub-layer 115, wherein the combined silicon oxide sub-layer and silicon nitride sub-layer is suitable for use as a rear surface passivation layer and a reflection layer for a solar cell. The silicon nitride sub-layer has a mass density of between about 2.5 and 3 g/cm³ and a hydrogen concentration of between about 6 atomic percent and 15 atomic percent. For example, the silicon nitride sub-layer may have a mass density equal to or less than 2.7 g/cm³. In one embodiment, a chamber pressure of 2 Torr may be maintained in the chamber and an RF power density from about 0.5 W/cm² to about 2.0 W/cm², such as about 1.0 W/cm², at a frequency of 13.56 MHz is applied to the showerhead 310 of the processing chamber 300 to generate a plasma for a period of time of about 20 seconds, while the second process gas mixture is delivered to the process volume 306. The silicon nitride sub-layer 117 may be deposited at a rate less than 2,000 Å per minute.

In one embodiment of the process 203-204, a chamber pressure of 2 Torr may be maintained in the processing chamber and an RF power intensity of 1 W/cm² at a frequency of 13.56 MHz is applied to the showerhead 310 of the processing chamber 300 to generate a plasma for a period of time of about 15 seconds, while the second process gas mixture is delivered to the process volume 306.

### EXAMPLE

### Example 1

A silicon oxide sub-layer is deposited on a rear surface of a p-type doped region of a substrate for a solar cell device. A silicon nitride sub-layer is then formed over the silicon oxide sub-layer, thereby forming a multilayer rear surface passivation layer on a solar cell substrate. The silicon oxide and silicon nitride sub-layer are formed according to the following conditions shown in Table 1, and are for a substrate area of 1,200×1,300 mm, which may be used to carry up to 56 wafers in a 7×8 arrangement.

TABLE 1

| | Silicon Oxide | Silicon Nitride |
|---|---|---|
| | Sub-Layer | Sub-Layer |
| Deposition Time (Sec.) | 15 | 18 |
| Temperature (° C.) | 390 | 390 |
| Pressure (Torr) | 1.2 | 1.5 |
| RF Power (Watts) | 5,500 | 10,000 |
| Spacing (mils) | 1,200 | 1,100 |
| N₂O flow rate (sccm) | 15,000 | N/A |
| N₂ flow rate (sccm) | N/A | 17,300 |
| TEOS flow rate (sccm) | 2,000 | 2,000 |

The spacing is between the showerhead and the substrate support. The deposition rate for the silicon oxide sub-layer was 3,000 Å per minute and had a thickness of 750 Å. The deposition rate for the silicon nitride sub-layer was about 1,665 Å per minute and had a thickness of 500 Å. Thus, the multilayer rear surface passivation layer had a total thickness of about 1,250 Å and was formed in just over 30 seconds using PECVD processes. The recombination carrier lifetime of the solar cell having the multilayer rear surface passivation layer was 750 μs. A silicon oxide layer and silicon oxide layer formed according to a conventional method only provided a lifetime of 75 μs. Thus, the solar cell lifetime improved 10 times using a multilayer rear surface passivation according to embodiments of the invention.

Embodiments of the invention generally provide various passivation advantages. For example, the multilayer rear surface passivation layer contains some hydrogen that can react with the dangling bonds of the silicon substrate to passivate the silicon surface layer and bulk layer. The hydrogen in the multilayer rear surface passivation layer can flow deeply into the silicon substrate during the firing process. Silicon surface passivation can be achieved regardless of whether or not a firing process is performed on the solar cell. Thus, embodiments of the invention provide passivation source that is a hydrogen source and a reflector, that is easy to etch or pattern compared to conventional rear surface passivation layers. The composition of the oxide and nitride are selected such that they are maximally compatible with the etch gel process or the laser opening process. Moreover, the silicon oxide sub-layer has a net amount of charge that helps prevent accumulation or formation of charged inversion layer, i.e. a layer of excess electrons in the silicon opposite the passivating layer; which layer of inverted charge can drain into backside contacts, causing a shunt current.

While the foregoing is directed to embodiments of the present invention, other and further embodiments of the invention may be devised without departing from the basic scope thereof, and the scope thereof is determined by the claims that follow.

What is claimed is:

1. A method of forming a multilayer rear surface passivation layer on a solar cell substrate, comprising:
forming a silicon oxide sub-layer having a net charge density of less than or equal to 2.1×10¹¹ Coulombs/cm² on a rear surface of a p-type doped region formed in a substrate comprising semiconductor material, the rear surface opposite a light receiving surface of the substrate; and
forming a silicon nitride sub-layer on the silicon oxide sub-layer.

2. The method of claim 1, wherein the silicon nitride sub-layer has a net charge density of less than or equal to 3.0×10¹² Coulombs/cm².

3. The method of claim 1, wherein the silicon oxide sub-layer has a hydrogen concentration from between about 1 at. % to 5 at. %.

4. The method of claim 1, wherein the silicon oxide sub-layer has a net negative charge density.

5. The method of claim 1, wherein forming the silicon oxide sub-layer and the silicon nitride sub-layer comprises:
flowing a first process gas mixture into a process volume of a processing chamber, wherein the first process gas mixture comprises:
a silicon-containing gas; and
an oxidizing gas;
depositing the silicon oxide sub-layer on the rear surface of the substrate;
flowing a second process gas mixture into the process volume, wherein the second process gas mixture comprises:
a silicon-containing gas; and
a nitrogen-containing gas; and
depositing the silicon nitride sub-layer on the silicon oxide sub-layer

6. The method of claim 5, wherein the silicon oxide sub-layer is deposited at 2,000 Å or more per minute and the silicon nitride sub-layer is deposited at more than 1,000 Å per minute.

7. The method of claim 5, wherein the silicon oxide sub-layer is deposited at a temperature between about 100° C. and 200° C. and the silicon nitride sub-layer is deposited at a temperature between about 250° C. and 200° C.

8. The method of claim 5, wherein a ratio of the oxidizing gas to the silicon-containing gas in the first gas mixture is between 5:1 and 10:1.

9. The method of claim 5, wherein a ratio of the silicon-containing gas to the nitrogen-containing gas in the second gas mixture is between 5:1 and 10:1.

10. The method of claim 1, wherein the silicon oxide sub-layer has a thickness between about 500 Å and 1,000 Å and the silicon nitride sub-layer has a thickness between about 250 Å and 1000 Å.

11. The method of claim 1, wherein the multilayer rear surface passivation layer has a total thickness between about 1,000 Å and 1,500 Å.

12. The method of claim 1, further comprising:
depositing a backside contact layer on the silicon nitride sub-layer; and
forming backside contacts on the substrate after depositing the backside contact layer, wherein the backside contacts traverse the multilayer rear surface passivation layer to electrically couple the backside contact layer with the semiconductor material.

13. The method of claim 1, further comprising:
patterning the multilayer rear surface passivation layer to expose the rear surface of the substrate; and
depositing a backside contact layer on the silicon nitride sub-layer after patterning the multilayer rear surface passivation layer.

14. A solar cell device, comprising:
a substrate comprising a semiconductor material, the substrate comprising a light receiving surface and a rear surface opposite the light receiving surface;
a multilayer rear surface passivation layer on the rear surface of a p-type doped region formed in the substrate, the multilayer rear surface passivation layer comprising:
a silicon oxide sub-layer having a net charge density of less than or equal to 2.1×10¹¹ Coulombs/cm² formed on the rear surface of the substrate; and
a silicon nitride-containing sub-layer formed on the silicon oxide sub-layer of the substrate;
a back contact layer comprising a conductive material on the multilayer rear surface passivation layer; and
a backside contact that traverses the multilayer rear surface passivation layer to electrically couple the back contact layer with the semiconductor material.

15. The solar cell device of claim 14, wherein the substrate comprises:
a base region comprising a p-type silicon, part of which forms the rear surface;
an emitter region comprising an n-type doped silicon;
a p-n junction region formed between the base region and the emitter region; and
an anti-reflective coating deposited on the emitter region.

16. The solar cell device of claim 14, wherein the conductive material is aluminum and the silicon oxide sub-layer comprises silicon dioxide.

17. The solar cell device of claim 14, wherein the silicon nitride sub-layer is between about 250 Å and about 1,000 Å and the silicon oxide sub-layer is between about 750 Å and about 1,000 Å.

18. The solar cell device of claim 17, wherein the multilayer rear surface passivation layer has a thickness between about 1,000 Å and about 1,500 Å.

19. The solar cell device of claim 14, wherein the substrate comprises a p-type substrate and the rear surface comprises a p-type doped region so that the rear surface multilayer passivation layer is on the p-type doped region.

20. The solar cell device of claim 14, wherein the silicon oxide sub-layer has a hydrogen concentration from between about 1 at. % to 5 at. %.
